(19) United States
(12) Patent Application Publication
(10) Pub. No.: US 2026/0321528 A1
(43) Pub. Date: Oct. 15, 2026

(54) TRANSPARENT CHASSIS SWITCH STRUCTURE WITH LEVITATION EFFECT

(71) Applicant: AMERICAN FUTURE TECHNOLOGY, City of Industry, CA (US)

(72) Inventor: You-Chi LIU, City of Industry, CA (US)

(21) Appl. No.: 19/531,028

(22) Filed: Feb. 5, 2026

(30) Foreign Application Priority Data
Feb. 17, 2025 (TW) 114105758

(51) Int. Cl. H01H 13/14; H01H 13/02; H01H 13/10; H05K 7/14; H05K 7/20

(52) U.S. Cl. CPC H01H 13/14; H01H 13/023; H01H 13/10; H05K 7/1427; H05K 7/20154; H05K 7/20418

(57) ABSTRACT

A transparent chassis switch structure with levitation effect, includes a chassis body including a transparent front panel, a transparent side panel, a transparent top cover with a light-transmitting plate and an air intake panel mounting portion and a switch mounting structure, a levitation switch including a switch holder base assembled on the switch mounting structure, a circuit board provided with a push-button switch and mounted in the switch holder base and a fixing shell mounted on the outside of the circuit board and having a pressing surface abutted against the push-button switch. The levitation switch is positioned at an angle on the chassis body by combining the transparent front panel, the transparent side panel and the transparent top cover, thereby creating an optimal levitation visual effect for the switch and providing the host with a good overall visual experience.

This application claims the priority benefit of Taiwan patent application number 114105758, filed on Feb. 17, 2025.

### BACKGROUND OF THE INVENTION

### 1. FIELD OF THE INVENTION

The present invention relates to a transparent chassis switch structure with levitation effect, particularly a levitation switch is mounted at an angle on three-party positions of a transparent front panel, at least one transparent side panel and a transparent top cover on a chassis body, thereby creating an optimal levitation visual effect for the switch and providing a good overall visual experience for the host.

### 2. DESCRIPTION OF THE RELATED ART

Nowadays, in order to gain a better share of the computer host consumer market and attract consumers' attention, computer hosts with distinctive appearances and visual effects have become one of the research targets for various manufacturers. For example, a unified color scheme or a visually appealing LED display can increase consumers' willingness to buy. Furthermore, the push-button switches on most computer chassis and cases are designed on a flat surface on the top or front panel of the chassis, requiring the user to press them vertically or horizontally. There is no design to assist the user in pushing or pressing the push-button switch. Using a switch is a long-term task, and over time, even small inconveniences can lead to user fatigue. This is a key area that those in this industry urgently need to research and improve.

### SUMMARY OF THE INVENTION

The main object of this invention is to provide a transparent chassis switch structure with levitation effect, comprising a chassis body, a levitation switch, and a ventilation module. The chassis body comprises a transparent front panel, at least one transparent side panel and a transparent top cover. The surface of the transparent front panel has a first light-transmitting surface, and the surface of the at least one transparent side panel has a second light-transmitting surface. The transparent top cover has a support plate, and a light-transmitting plate with a third light-transmitting surface is then assembled on a supporting surface at the top of the support plate, and an air intake panel mounting portion is provided on the light-transmitting plate. A switch mounting structure is formed between the transparent front panel, the at least one transparent side panel and the transparent top cover of the chassis body, wherein the three-party positions are beveled at an angle. The switch mounting structure has a first intersection between the transparent front panel and the at least one transparent side panel, a second intersection between the transparent front panel and the transparent top cover, and a third intersection between the at least one transparent side panel and the transparent top cover. The levitation switch has a switch holder base assembled on the switch mounting structure, and an assembly space is formed in the switch holder base for assembling a circuit board. The circuit board has a push-button switch on the surface thereof, and a fixing shell is assembled on the outside of the circuit board, with a pressing surface formed on the fixing shell abutting against the push-button switch. The ventilation module has an air intake panel mounted on the air intake panel mounting portion of the light-transmitting plate. The levitation switch is mounted at an angle on the chassis body by combining the transparent front panel, the at least one transparent side panel and the transparent top cover to create an optimal levitation visual effect for the switch and provides the host with a good overall visual experience.

Another object of this invention is that the switch mounting structure comprises a first switch mounting portion that is beveled and is disposed on the transparent front panel adjacent to the at least one transparent side panel, a second switch mounting portion that is beveled and is disposed on the support plate adjacent to the transparent front panel and the at least one transparent side panel, and an extension plate extending from one side of the second switch mounting portion.

Still another object of this invention is that the first switch mounting portion has at least one first mounting hole, the second switch mounting portion has at least one second mounting hole, and the extension plate has a plurality of locking holes.

Still another object of this invention is that a positioning groove is provided on a bottom plate of the switch holder base, and a positioning block protruding from the bottom surface of the circuit board passes through the positioning groove of the switch holder base.

Still another object of this invention is that the switch holder base further comprises at least one first fixing hole located on the bottom plate and two positioning holes provided on respective inner wall surfaces of two opposite sides thereof; the circuit board further comprises at least one second fixing hole recessed on at least one side thereof corresponding to the at least one first fixing hole; the fixing shell further comprises at least one long first positioning arm extending downward from a bottom thereof and inserted through the at least one second fixing hole and the at least one first fixing hole, two second positioning arms respectively extending downward from two sides thereof and far from the at least one first positioning arm, a positioning rod extending outward from each of the two second positioning arms and fixed within one respective positioning hole of the switch holder base, and a stop block protruded from a bottom of each of the at least one first positioning arm.

Still another object of this invention is that the fixing shell further comprises a plurality of third fixing holes provided around the periphery thereof for mounting a top cover; the top cover comprises an opening that exposes the pressing surface of the fixing shell, a plurality of three-dimensional surfaces gradually extending upward at the periphery thereof, and a plurality of fixing rods extending downward and respectively mounted into each of the plurality of third fixing holes of the fixing shell.

### BRIEF DESCRIPTION OF THE DRAWINGS

FIG. 1 is a three-dimensional external view of the transparent chassis switch structure with levitation effect of the present invention.

FIG. 2 is a three-dimensional exploded view of the transparent chassis switch structure with levitation effect of the present invention.

FIG. 3 is a schematic assembly diagram of the levitation switch of the present invention.

FIG. 4 is a three-dimensional exploded view of the heat dissipation base of the present invention.

FIG. 5 is a three-dimensional exploded view of the ventilation module of the present invention.

FIG. 6 is a three-dimensional exploded view of the ventilation module of the present invention from another viewing angle.

FIG. 7 is a three-dimensional exploded view of the levitation switch of the present invention.

FIG. 8 is a three-dimensional exploded view of the levitation switch of the present invention from another viewing angle.

### DETAILED DESCRIPTION OF THE PREFERRED EMBODIMENT

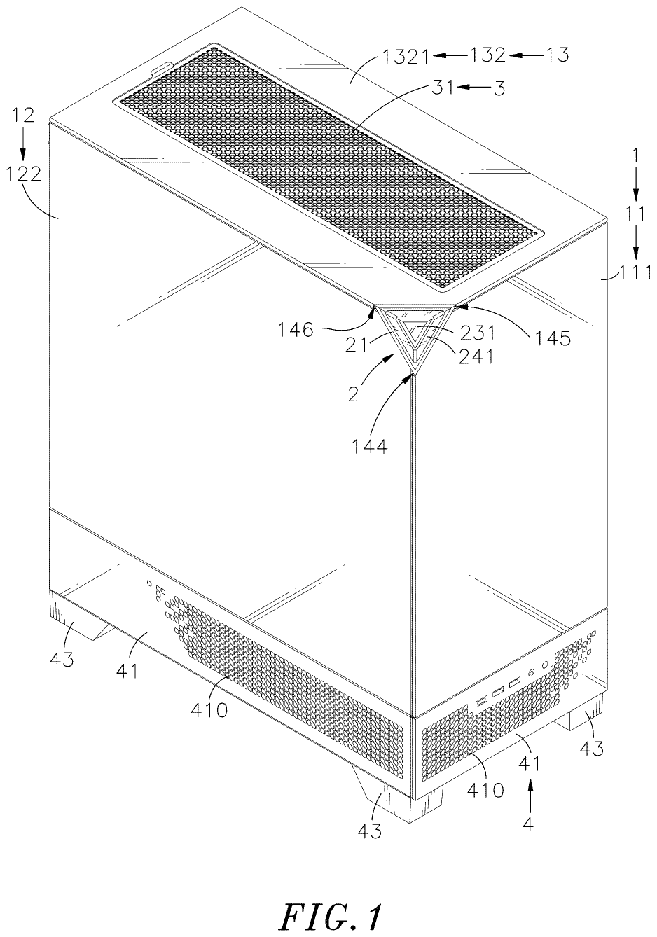

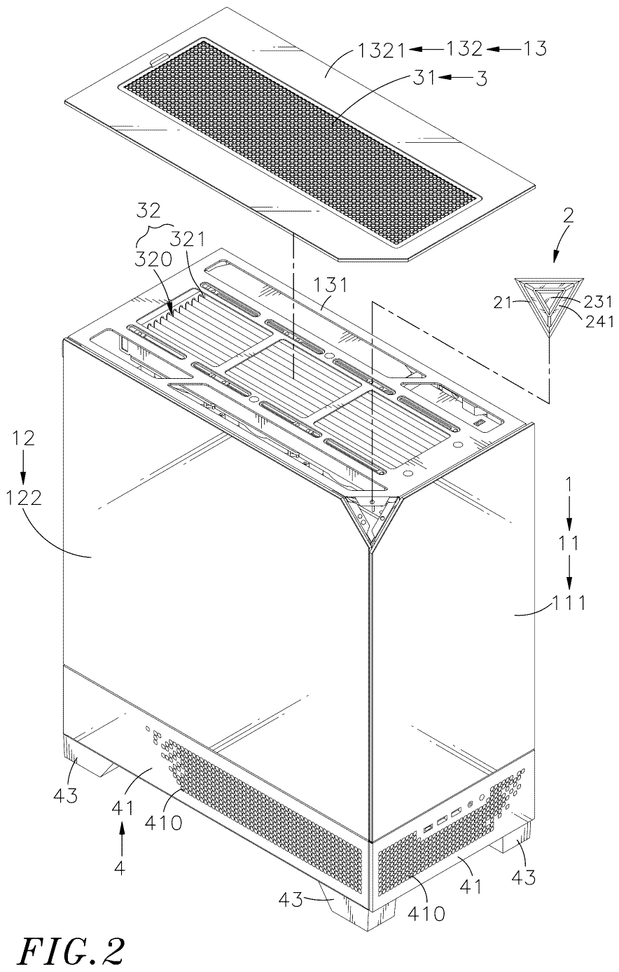

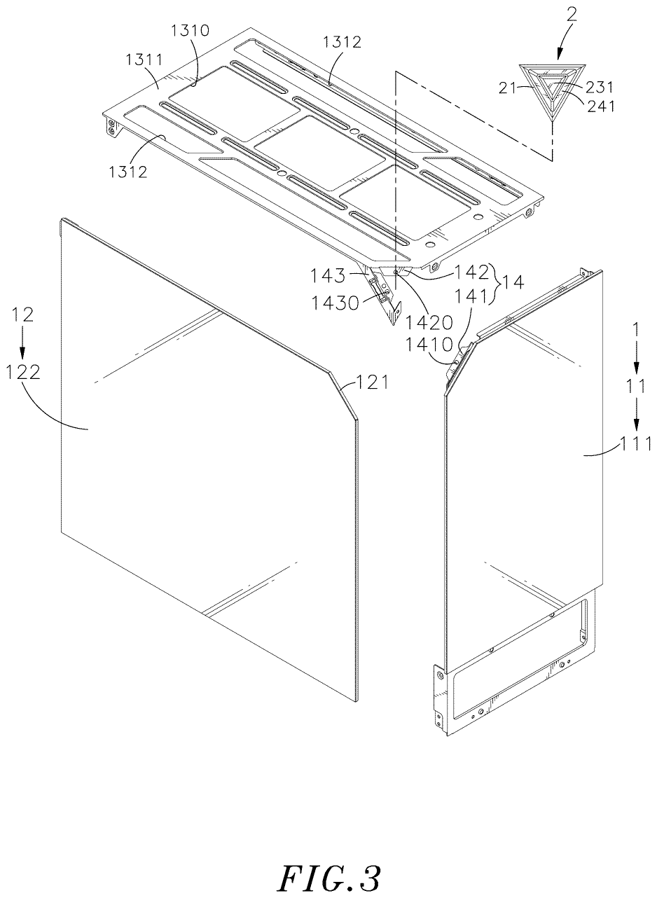

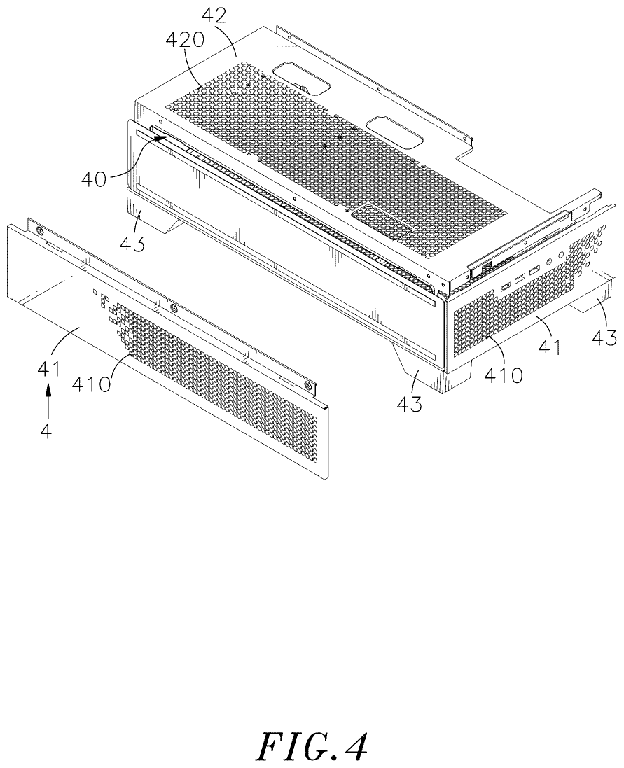

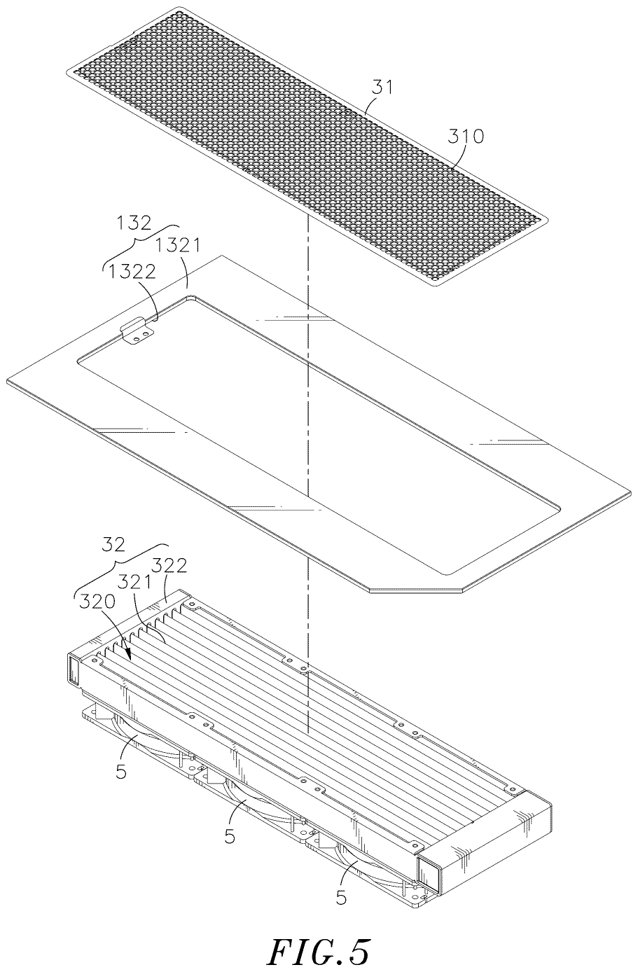

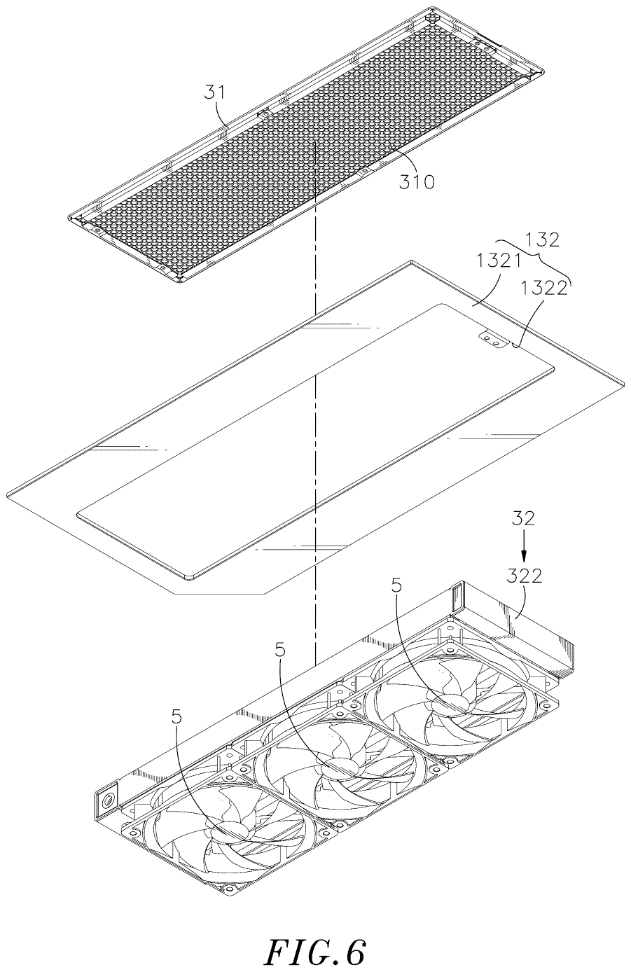

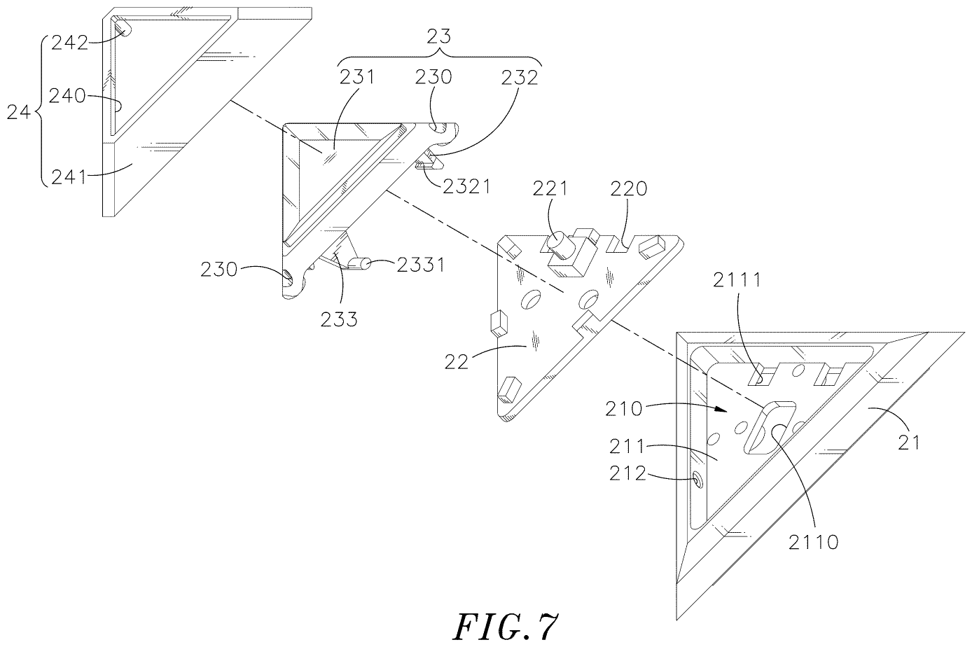

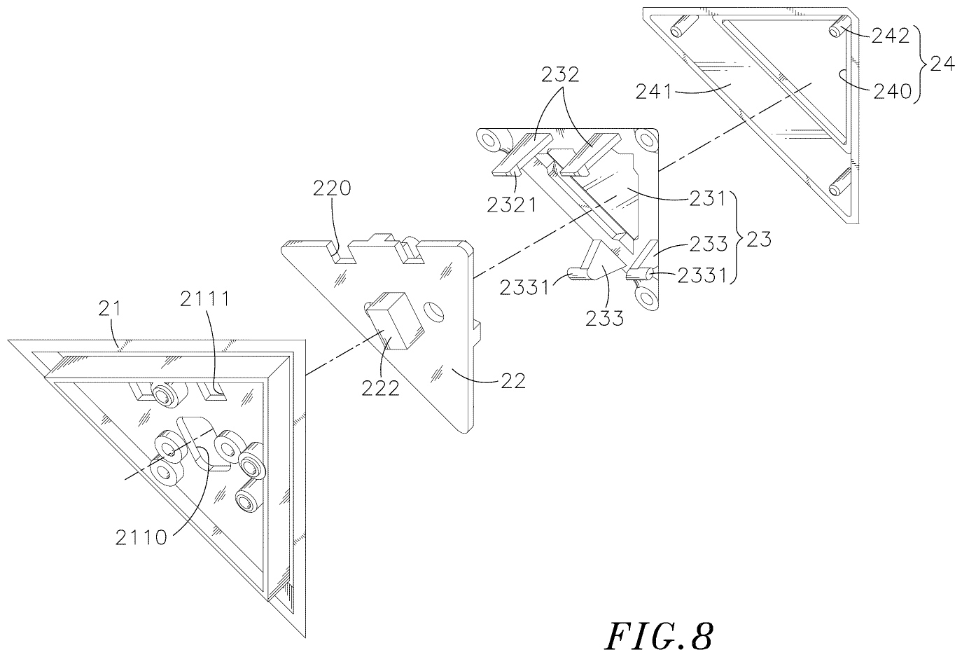

Please refer to FIGS. 1 to 8. The transparent chassis switch structure with levitation effect of this invention mainly comprises a chassis body 1, a levitation switch 2 and a ventilation module 3. The connection relationship of the aforementioned components is as follows:

The chassis body 1 comprises a transparent front panel 11, at least one transparent side panel 12 and a transparent top cover 13. The transparent front panel 11 has a first light-transmitting surface 111 formed on a surface thereof. The at least one transparent side panel 12 has one top corner thereof beveled to form a limiting cut surface 121 adjacent to the transparent front panel 11, and the at least one transparent side panel 12 further has a second light-transmitting surface 122 formed on a surface thereof. The transparent top cover 13 comprises a support plate 131, and a light-transmitting plate 132 with a third light-transmitting surface 1321 is assembled at a supporting surface 1311 of a top of the support plate 131, and the light-transmitting plate 132 is provided with an air intake panel mounting portion 1322. The support plate 131 has a surface thereof provided with at least one air inlet 1310 and a plurality of buffer openings 1312 located around each air inlet 1310. A switch mounting structure 14 is formed between the transparent front panel 11, the at least one transparent side panel 12 and the transparent top cover 13 and is tilted at an angle in combination with the three-party positions. The switch mounting structure 14 comprises a first switch mounting portion 141 that is beveled and disposed on the transparent front panel 11 adjacent to the at least one transparent side panel 12, a second switch mounting portion 142 that is beveled and disposed on the support plate 131 adjacent to the transparent front panel 11 and the at least one transparent side panel 12, and an extension plate 143 with a plurality of locking holes 1430 extending from one side of the second switch mounting portion 142.

The first switch mounting portion 141 is provided with at least one first mounting hole 1410, and the second switch mounting portion 142 is provided with at least one second mounting hole 1420.

The levitation switch 2 comprises a switch holder base 21 assembled on the switch mounting structure 14, a circuit board 22 mounted in the switch holder base 21, a fixing shell 23 mounted on an outside of the circuit board 22, and a top cover 24 covering a periphery of the fixing shell 23. The switch holder base 21 comprises a bottom plate 211, a positioning groove 2110 and at least one first fixing hole 2111 located on the bottom plate 211, an assembly space 210 formed therein for assembling the circuit board 22, and two positioning holes 212 provided on inner wall surfaces of two opposite sides thereof. The circuit board 22 comprises a push-button switch 221 mounted on a surface thereof, at least one second fixing hole 220 recessed on at least one side thereof corresponding to the at least one first fixing hole 2111, and a positioning block 222 protruded from a bottom surface thereof and passing through the positioning groove 2110 of the switch holder base 21. The fixing shell 23 comprises a pressing surface 231 formed on a surface thereof and abutted against the push-button switch 221, at least one long first positioning arm 232 extending downward from a bottom thereof and inserted through the at least one second fixing hole 220 and the at least one first fixing hole 2111, a stop block 2321 protruded from a bottom of each of the at least one first positioning arm 232, two second positioning arms 233 respectively extending downward from two sides thereof and far from each of the at least one first positioning arm 232, and a positioning rod 2331 extending outward from each of two second positioning arms 233 and fixed within one respective positioning hole 212 of the switch holder base 21, and a plurality of third fixing holes 230 provided around the periphery thereof for mounting the top cover 24. The top cover 24 comprises an opening 240 that exposes the pressing surface 231 of the fixing shell 23, a plurality of three-dimensional surfaces 241 gradually extending upward at a periphery thereof, and a plurality of fixing rods 242 extending downward and respectively mounted into each of the plurality of third fixing holes 230 of the fixing shell 23.

The ventilation module 3 comprises an air intake panel 31 provided with a plurality of ventilation holes 310 and disposed on the air intake panel mounting portion 1322 of the light-transmitting plate 132, and a heat dissipation device 32 assembled at a bottom of the support plate 131 of the chassis body 1. The heat dissipation device 32 comprises an air outlet 320, a plurality of heat dissipation fins 321 mounted in the air outlet 320 corresponding to each air inlet 1310, heat-conducting parts 322 located on two opposite sides thereof and connected to each of the plurality of heat dissipation fins 321 for heat transfer, and at least one preset fan 5 assembled at a bottom thereof.

Furthermore, a heat dissipation base 4 is further assembled at a bottom of the chassis body 1. The heat dissipation base 4 comprises a plurality of heat dissipation plates 41 arranged around a periphery thereof, a plurality of first heat dissipation holes 410 located on surfaces of the plurality of heat dissipation plates 41, a heat dissipation buffer space 40 formed therein, two heat dissipation cover plates 42 respectively located at both top and bottom sides thereof, a plurality of second heat dissipation holes 420 located on surfaces of the two heat dissipation cover plates 42, and a plurality of support brackets 43 provided at various points around a bottom periphery thereof.

The switch mounting structure 14 further comprises a first intersection 144 between the transparent front panel 11 and the at least one transparent side panel 12, a second intersection 145 between the transparent front panel 11 and the transparent top cover 13 and a third intersection 146 between the at least one transparent side panel 12 and the transparent top cover 13 at an intersection of the three-party positions of the transparent front panel 11, the at least one transparent side panel 12 and the transparent top cover 13, so that three points of the first intersection 144, the second intersection 145 and the third intersection 146 are intersected to form an triangle of the switch mounting structure 14.

Furthermore, the levitation switch 2 is arranged in a triangular shape to match the three-point intersection of the switch mounting structure 14, and is tilted at an angle on one side of the chassis body 1 for the convenience of the user pressing the power button. Its tilt angle is designed to accommodate the placement of the host. When the host is placed under the desk, it is easy to press and apply force; when the host is placed on the desk, it also works with the tilted push-button switch 221. Compared to traditional push-button switches located on the top surface or front panel, the levitation switch 2 is easier to press, saving the users' effort and improving convenience. The power switch on a computer host is a component that the users press at least once a day, and its location must be convenient for the users during long-term operation. If the pressing position is inconvenient, the users may not feel anything at first, but over time it will cause fatigue for the users. Simply changing the position of the switch can greatly reduce user fatigue, which is the effect of the tilt angle and position design of the levitation switch 2 in this invention.

When assembling the transparent chassis switch structure with levitation effect of the present invention, the switch mounting structure 14 is formed between the transparent front panel 11, the at least one transparent side panel 12 and the transparent top cover 13 of the chassis body 1, and is tilted at an angle in combination with the three-party positions. The levitation switch 2 is then assembled onto the switch mounting structure 14, and secured to the switch holder base 21 of the levitation switch 2 by means of a plurality of preset fasteners (not shown in the figures) passing through the at least one first mounting hole 1410, the at least one second mounting hole 1420 and the plurality of locking holes 1430 of the switch mounting structure 14. The circuit board 22 is further assembled inside the assembly space 210 of the switch holder base 21, and the positioning block 222 protruding from the bottom surface of the circuit board 22 forms a positioning point at the positioning groove 2110 of the bottom plate 211 of the switch holder base 21. The fixing shell 23 is then assembled onto the circuit board 22, and a bottom of the pressing surface 231 of the fixing shell 23 abuts against a surface of the push-button switch 221 on the circuit board 22. Meanwhile, the at least one long first positioning arm 232 extending downward from the fixing shell 23 is inserted through each of the at least one second fixing hole 220 and exits through each of the at least one first fixing hole 2111, so that the stop block 2321 located at an end of the at least one first positioning arm 232 exits the switch holder base 21, and the two second positioning arms 233, which are shorter and located away from a side of each of the at least one first positioning arm 232, are passed through the circuit board 22, and the positioning rods 2331 extending from the two second positioning arms 233 are then assembled into the two positioning holes 212 of the switch holder base 21 to form a positioning. The top cover 24 is then positioned on each of the plurality of third fixing holes 230 of the fixing shell 23 through the plurality of fixing rods 242, so that the pressing surface 231 of the fixing shell 23 is exposed at the opening 240 of the top cover 24, thereby completing the assembly of the levitation switch 2 of the present invention.

Furthermore, the air intake panel 31 of the aforementioned ventilation module 3 is mounted on the air intake panel mounting portion 1322 of the light-transmitting plate 132 of the chassis body 1, and a bottom side of the light-transmitting plate 132 relies on the support plate 131 to distribute gravity. The heat dissipation device 32 is assembled at the bottom of the support plate 131, the heat dissipation device 32 is provided with the air outlet 320 corresponding to each air inlet 1310, and the at least one preset fan 5 is assembled at the bottom of the heat dissipation device 32.

In addition, the heat dissipation base 4 at the bottom of the chassis body 1 is assembled from the plurality of heat dissipation plates 41 to form the heat dissipation buffer space 40 inside, and the plurality of support brackets 43 are provided at various points around the bottom periphery of the heat dissipation base 4 to provide support.

The aforementioned transparent front panel 11, at least one transparent side panel 12 and transparent top cover 13 are made of glass and are beveled at an angle in combination with the three-party positions on the chassis body 1 in conjunction with the levitation switch 2. By utilizing the light-transmitting properties of glass, a levitation effect is created where the switch appears to be suspended in mid-air, providing the host with a pleasing visual experience and thus stimulating consumer desire. The covering of the top cover 24 of the levitation switch 2 with the plurality of three-dimensional surfaces 241 enhances the sense of depth of the levitation switch 2 and gives it a more levitation effect. The transparent front panel 11, the at least one transparent side panel 12 and the transparent top cover 13 can also be made of transparent acrylic sheet or other transparent materials, which are materials that can create a switch levitation visual effect. Such simple and uniform variations and modifications do not limit the scope of protection of this invention, and are therefore clearly stated.

Furthermore, the top cover 24 of the aforementioned levitation switch 2 can also be made of transparent materials such as glass, acrylic sheet, or other transparent materials. LEDs or other light-emitting elements can be installed on the switch holder base 21 or the circuit board 22 of the levitation switch 2 to enhance the light-emitting effect inside the levitation switch 2 and further enhance the levitation sensation on the chassis body 1.

Furthermore, when the aforementioned levitation switch 2 is pressed, the at least one long first positioning arm 232 on the fixing shell 23 extends downward as it is pressed, thus providing a long-stroke pressing feel. This pressure is released after the pressing surface 231 presses against the push-button switch 221 at the bottom. At this point, the two shorter second positioning arms 233 on the fixing shell 23 are positioned by the positioning rod 2331 and will not move excessively. As the pressure is released, the at least one first positioning arm 232 can spring back upward to its original position. The stop block 2321 at the bottom of the at least one first positioning arm 232 will block the bottom plate 211 of the switch holder base 21 when the at least one first positioning arm 232 bounces back upward, so as to prevent the at least one first positioning arm 232 from detaching from the switch holder base 21.

Furthermore, the light-transmitting plate 132 of the transparent top cover 13 is preferably made of glass material with good light transmission. Therefore, the present invention assembles the air intake panel 31 onto the air intake panel mounting portion 1322, which is formed by cutting out a hole in the glass, to maintain ventilation inside the chassis body 1 in an environment with good light transmission. To prevent the weight of the glass from affecting the overall support of the chassis body 1, the bottom side of the light-transmitting plate 132 is provided with the support plate 131 for support. The heat dissipation device 32 assembled at the bottom of the support plate 131 provides air cooling through the at least one preset fan 5 at the bottom. This heat source inside the chassis body 1 is conducted to each of the plurality of heat dissipation fins 321 through the heat-conducting parts 322 of the heat dissipation device 32. Then, the air blown out by the at least one preset fan 5 passes through the plurality of ventilation holes 310 on the air intake panel 31 and is discharged outside the chassis body 1. The plurality of buffer openings 1312 on the support plate 131 guide any air that cannot be blown out back into the chassis body 1 for re-air cooling.

As described above, the bottom of the chassis body 1 is further assembled with the heat dissipation base 4. Preferably, the chassis body 1 is assembled by using the transparent front panel 11, the at least one transparent side panel 12 and the transparent top cover 13 made of glass to create an optimal levitation visual effect for the switch. However, even with the ventilation module 3, the heat dissipation effect may not be sufficient due to the glass assembly on at least three sides. Therefore, the heat dissipation base 4 can conduct heat from inside the chassis body 1 to the heat dissipation buffer space 40 to prevent heat from accumulating inside the chassis body 1. The plurality of heat dissipation plates 41 and the two heat dissipation cover plates 42 surrounding the heat dissipation base 4 are for discharging the heat energy stored inside the heat dissipation base 4.

Furthermore, the main object of this invention is to address the levitation switch 2, which is beveled at an angle in combination with the three-party positions on the chassis body 1, namely the transparent front panel 11, the at least one transparent side panel 12 and the transparent top cover 13, thereby creating an optimal levitation visual effect for the switch. The secondary object of this invention is the use of glass material with good light transmission for the light-transmitting plate 132 of the transparent top cover 13, and the assembly of the air intake panel 31 onto the air intake panel mounting portion 1322 formed by cutting out a hole in the glass, thereby maintaining the ventilation effect inside the chassis body 1 while ensuring good light transmission.

What the invention claimed is:

1. A transparent chassis switch structure with levitation effect, comprising:
a chassis body comprising a transparent front panel, at least one transparent side panel, a transparent top cover and a switch mounting structure, said transparent front panel comprising a first light-transmitting surface formed on a surface thereof, said at least one transparent side panel comprising a second light-transmitting surface formed on a surface thereof, said transparent top cover comprising a support plate and a light-transmitting plate, said support plate comprising a supporting surface on a top thereof, said light-transmitting plate being assembled on said supporting surface of said support plate, said light-transmitting plate comprising a third light-transmitting surface and an air intake panel mounting portion, said switch mounting structure being formed between said transparent front panel, said at least one transparent side panel and said transparent top cover and being tilted at an angle in combination with the three-party positions of said transparent front panel, said at least one transparent side panel and said transparent top cover, said switch mounting structure comprising a first intersection between said transparent front panel and said at least one transparent side panel, a second intersection between said transparent front panel and said transparent top cover and a third intersection between said at least one transparent side panel and said transparent top cover;
a levitation switch assembled on said switch mounting structure, said levitation switch comprising a switch holder base assembled on said switch mounting structure, an assembly space formed in said switch holder base, a circuit board mounted in said assembly space inside said switch holder base and a fixing shell mounted on an outside of said circuit board, said circuit board comprising a push-button switch mounted on a surface thereof, said fixing shell comprising a pressing surface abutted against said push-button switch; and
a ventilation module comprising an air intake panel disposed on said air intake panel mounting portion of said light-transmitting plate.

2. The transparent chassis switch structure with levitation effect as claimed in claim 1, wherein said levitation switch is arranged in a triangular shape, and is assembled at said switch mounting structure.

3. The transparent chassis switch structure with levitation effect as claimed in claim 1, wherein said switch mounting structure comprises a first switch mounting portion that is beveled and is disposed on said transparent front panel adjacent to said at least one transparent side panel, a second switch mounting portion that is beveled and is disposed on said support plate adjacent to said transparent front panel and said at least one transparent side panel, and an extension plate extending from one side of said second switch mounting portion.

4. The transparent chassis switch structure with levitation effect as claimed in claim 3, wherein said first switch mounting portion comprises at least one first mounting hole, said second switch mounting portion comprises at least one second mounting hole, and said extension plate comprises a plurality of locking holes.

5. The transparent chassis switch structure with levitation effect as claimed in claim 1, wherein said switch holder base comprises a bottom plate, a positioning groove located on said bottom plate; said circuit board comprises a positioning block protruding from a bottom surface thereof passes through said positioning groove of said switch holder base.

6. The transparent chassis switch structure with levitation effect as claimed in claim 1, wherein said switch holder base further comprises at least one first fixing hole located on said bottom plate and two positioning holes provided on respective inner wall surfaces of two opposite sides thereof; said circuit board further comprises at least one second fixing hole recessed on at least one side thereof corresponding to said at least one first fixing hole; said fixing shell further comprises at least one long first positioning arm extending downward from a bottom thereof and inserted through said at least one second fixing hole and said at least one first fixing hole, two second positioning arms respectively extending downward from two sides thereof and far from said at least one first positioning arm, and a positioning rod extending outward from each of said two second positioning arms and fixed within one respective said positioning hole of said switch holder base.

7. The transparent chassis switch structure with levitation effect as claimed in claim 6, wherein said fixing shell further comprises a stop block protruded from a bottom of each of said at least one first positioning arm.

8. The transparent chassis switch structure with levitation effect as claimed in claim 1, wherein said fixing shell further comprises a plurality of third fixing holes provided around the periphery thereof for mounting a top cover; said top cover comprises an opening that exposes said pressing surface of said fixing shell, a plurality of three-dimensional surfaces gradually extending upward at a periphery thereof, and a plurality of fixing rods extending downward and respectively mounted into each of said plurality of third fixing holes of said fixing shell.

9. The transparent chassis switch structure with levitation effect as claimed in claim 1, further comprising a heat dissipation base assembled at a bottom of said chassis body, said heat dissipation base comprising a plurality of heat dissipation plates arranged around a periphery thereof, a plurality of first heat dissipation holes located on surfaces of said plurality of heat dissipation plates, a heat dissipation buffer space formed therein, two heat dissipation cover plates respectively located at both top and bottom sides thereof and a plurality of second heat dissipation holes located on surfaces of said two heat dissipation cover plates.
